(19) United States
(12) Patent Application Publication
(10) Pub. No.: US 2024/0363342 A1
(43) Pub. Date: Oct. 31, 2024

(54) METHODS AND STRUCTURES FOR REDUCING DEFORMATIONS OF GALLIUM NITRIDE (GaN) DEVICES

(71) Applicant: Robert Bosch GmbH, Stuttgart (DE)

(72) Inventors: BO CHENG, Malden, MA (US); JENS BARINGHAUS, Sindelfingen (DE); CHARLES TUFFILE, Swansea, MA (US)

(21) Appl. No.: 18/140,201

(22) Filed: Apr. 27, 2023

(51) Int. Cl. H01L 21/02; H01L 29/20

(52) U.S. Cl. CPC H01L 21/02592; H01L 21/02373; H01L 21/0254; H01L 29/2003

(57) ABSTRACT

Methods and structures for reducing process and final deformation of gallium nitride (GaN) semiconductor devices are provided. The methods include forming at least one multi-layered structure on at least one surface(s) a semiconductor substrate. The multi-layered structure(s) are formed by applying at least a first amorphous layer on at least one surface(s) of the semiconductor substrate, the first amorphous layer having a first thermal expansion coefficients (CTE), and applying a second amorphous layer on the first amorphous layer, the second amorphous layer having a second thermal expansion coefficient, different from the first thermal expansion coefficient.

### TECHNICAL FIELD

The present disclosure relates to methods and structures for reducing deformations of semiconductor wafer substrates occurring due to processing steps, particularly in the fabrication of gallium nitride (GaN) semiconductor devices.

### BACKGROUND

In recent years, the wide bandgap gallium nitride (GaN) semiconductor material and its alloys (AlGaN, InGaN, AlInGaN), have been considered promising materials for a variety of applications, including in many microelectronic applications as field-effect transistors (FETs), high electron mobility transistors (HEMTs), and diodes. GaN's high breakdown electric field and high mobility makes GaN-based devices suitable for incorporation in harsh environments, such as for very high power and microwave frequencies, since these devices are capable of handling high current and high voltage.

Substrates which are used for GaN growth and subsequently GaN device fabrication, include silicon-based substrates, such as doped or un-doped silicon substrates, silicon carbide (SiC), silicon-on-insulator (SOI), and silicon on-sapphire (SOS). Silicon-based substrates are particularly suitable as they are typically low cost, and readily available materials. However, the problem that exists with using silicon-based substrates (and other wafer substrates) for growing GaN layers arises out of the material differences in thermal expansion rates and in lattice parameters (lattice constants), commonly referred to as lattice mismatch.

Gallium Nitride has a different thermal expansion coefficient (CTE) than many of the silicon-based substrate materials it is commonly deposited on. This means that the rate of expansion of the GaN material during heating or cooling will differ from the rate of expansion of the substrate material. This difference in thermal expansion between the various layers can lead to large deformations in the shape of the layered structure during deposition and cool down of the structure, resulting in warping, bowing, and potentially cracking of the GaN layers deposited on the substrate. This is commonly exhibited once the GaN has been deposited at high temperatures and the structure undergoes a cooling period once deposition has completed. Once there is cracking in the semiconductor layer and/or warping or bowing of the overall structure, it is no longer suitable for device fabrication and its intended final application.

In addition to thermal mismatch, the lattice constants of GaN also differ from those of silicon (and other substrate materials), which results in lattice mismatch between these materials. Lattice mismatch can lead to the formation of crystal defects in GaN layers and these defects can ultimately propagate within the deposited layers and negatively impact the performance of the resulting semiconductor device. Independent of these defects, warping and bowing of the structure can also occur if there is large strain on the epitaxial GaN layers resulting from lattice mismatch. This strain occurs during growth of the GaN layer, at extremely elevated temperatures, and contributes to warping and bowing, irrespective of the deformation already occurring from thermal expansion differences.

These defects and deformation issues have typically been addressed in the past through incorporation of buffer layers deposited on the substrate, prior to GaN growth. These buffers layers can include a nucleation layer of AlN and/or graded AlₓGa₁₋ₓN layer, wherein 0<x<1. However, incorporation of buffer layers prior to GaN deposition, has only helped mitigate deformation of thin GaN films, where the intended GaN devices only requires a thin film layer. Deformation problems still persist for devices which require thick GaN layers for fabrication (e.g., 10 μm or higher).

The degree to which bowing and warping of the structure will occur, depends heavily on the thickness of the deposited GaN layer, with thicker deposited layers displaying a higher degree of warping or bowing in the final semiconductor structure. Therefore there remains a need for methods of reducing process deformations of GaN semiconductor structures, having thick GaN deposited layers.

### SUMMARY

Described herein are methods and structures for reducing process deformation of gallium nitride (GaN) semiconductor devices during a manufacturing process thereof. More particularly, the methods and structures disclosed herein offset and reduce bowing and warping of semiconductor substrates which occurs during a fabrication of thick GaN layer devices.

In one embodiment a method of reducing process or final deformation of a gallium nitride (GaN) semiconductor device during a manufacturing process is disclosed. The method includes forming at least one multi-layered structure on at least one surface(s) a semiconductor substrate and depositing a gallium nitride (GaN) semiconductor layer on the semiconductor substrate. The at least one multi-layered structure is formed by applying a first amorphous layer on the at least one surface(s) of the semiconductor substrate, the first amorphous layer having a first thermal expansion coefficients (CTE), and applying a second amorphous layer on the first amorphous layer, the second amorphous layer having a second thermal expansion coefficient, different from the first thermal expansion coefficient.

In some embodiments, the first amorphous layer materials can be selected from SiN, SiCₓO₍₁₋ₓ₎, SiC, SiNRO₍₁₋ₓ₎, Al₂O₃, and Cr₂O₃, or a combination thereof, wherein 0<x<1, and the second amorphous layer materials are selected from SiO₂, SiCₓN₍₁₋ₓ₎, or a combination thereof, wherein 0<x<1. These materials are selected so that a first amorphous layer has a CTE greater than the substrate layer it is deposited on, and the second amorphous layer has a CTE less than the substrate layer in the given embodiment. The temperature of deposition for the first and second amorphous layers is chosen so that it can effectively counter the deformations occurring during heating and cooling processes during fabrication of the device.

In one embodiment the temperature of deposition for the first amorphous layer is in the range of about 200° C.-400° C. The second amorphous layer is deposited at a temperature range of about 800° C.-1100° C.

Other embodiments are disclosed where a multi-layered structure used for reducing the deformations in the wafer substrate can be deposited on various surfaces of a substrate, including a top side surface. For example a multi-layered structure is deposited on a top side of a substrate. In this embodiment, an SOI substrate is used having substrate base layer, insulator layer and silicon top layer. Prior to deposition of the insulator layer and silicon top layer, a first amorphous layer can be deposited on the silicon base layer, followed by a second amorphous layer deposited onto the first amorphous layer. Other additional amorphous layers can also be deposited, where three, four, five, six layers and so on are deposited for purposes of offsetting and mitigating substrate deformation. For example, two or three different amorphous layers are deposited first having a CTE greater than that of the silicon base layer, and then an additional two or three amorphous layers are deposited having materials with a CTE less than that of the silicon base layer.

Also disclosed are semiconductor devices, fabricated according to the methods described herein, having multi-layered structures for purposes of deformation compensation. In one embodiment semiconductor device is disclosed having at least one multi-layered structure(s) formed on at least one surface(s) a semiconductor substrate, and a gallium nitride (GaN) semiconductor layer.

### Selected Definitions

As used herein, the term “silicon-based substrate” refers to any substrate that includes a silicon surface. Examples of silicon based substrates referenced herein include substrates that are formed almost entirely of silicon, such as for example, bulk silicon wafers. Additionally, silicon based substrates also refer to silicon-on-insulator (SOI) substrates, which have a layered design of silicon-insulator-silicon, wherein the insulator layer is typically SiO₂, and a thin crystalline silicon top layer. The term silicon based substrate will also include silicon-on-sapphire substrates (SOS), or any general substrate having a silicon top layer, such as composite type substrates that have a silicon wafer bonded to another material such as diamond, AlN, or other polycrystalline materials.

As used herein, references to “a surface” or “at least one surface” of semiconductor substrate can refer to a bottom side surface, a top side surface, or an interlayer surface of a semiconductor substrate which is comprised of a multitude of substrate layers. For example, in an silicon-on-insulator (SOI) type substrate, a surface can be defined as the bottom side surface of the silicon base layer, a top side surface of the wafer referring to any surface which is opposing to the bottom side, or an internal surface of SOI substrate, such as the surface between a bulk silicon base layer and an insulator layer, or between the insulator layer and top silicon layer. Or in a configuration where a general substrate has a silicon top layer, a surface can also refer to the internal surface between the general substrate and the silicon top layer.

As used herein a “bottom side” of a semiconductor substrate refers to a side of the substrate which is opposite the side of semiconductor layer deposition. A “top side” refers to the general side of the substrate wherein the semiconductor layer deposition typically occurs. The term “top side” is not used in this disclosure to mean only that a layer is deposited on the upper most substrate layer, but can include deposition of layers which are opposite the bottom side, but are interlayers within the substrate, such as is the case within an SOI substrate.

As used herein the term “process deformation” refers to structural deviations of a substrate or device which occur during processing steps, such as heating, deposition/growth steps, or cooling steps. The term “final deformation” references the structural deviation that results on the substrate or device, once all the processing steps have concluded.

The term “thermal expansion coefficient”, or “coefficient of thermal expansion” or “CTE”, refer to the same parameter, and may be used interchangeably throughout the disclosure. The terms refer to a measure of a particular material's expansion or contraction per degree of temperature.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the present disclosure.

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z

### BRIEF DESCRIPTION OF THE DRAWINGS

FIG. 1A is a cross-section view of GaN semiconductor device formed on an SOI substrate, without incorporation of a multi-layered structure for deformation compensation.

FIG. 1B s is a graphical depiction of simulation of deformation per growth phases for the device shown in FIG. 1A.

FIG. 2A is a cross-section view of GaN semiconductor device having bottom side multi-layered structure deposited on an SOI substrate, according to an embodiment disclosed herein.

FIG. 2B is a graphical depiction of simulation of deformation per growth phases for the device configuration shown in FIG. 2A.

FIG. 3A shows a structure including a substrate, semiconductor layer, and buffer layers according to an example embodiment;

FIG. 3B is a graphical depiction of simulation of deformation per growth phases for the device configuration shown in FIG. 3A.

FIG. 4 is a cross-section view of GaN semiconductor device having a top side multi-layered structure deposited on an SOI substrate, according to an embodiment disclosed herein.

FIG. 5 is a cross-section view of GaN semiconductor device having a top side and bottom side multi-layered structure deposited on an SOI substrate, according to an embodiment disclosed herein.

FIG. 6 is a cross-section view of GaN semiconductor device having at least one multi-layered structure deposited on a general substrate, according to an embodiment disclosed herein.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Described herein are methods and structures for reducing process deformation of gallium nitride (GaN) semiconductor devices during a manufacturing process thereof. More particularly, the methods and structures disclosed herein offset and reduce bowing and warping of semiconductor substrates which occurs during a fabrication of thick GaN layer devices.

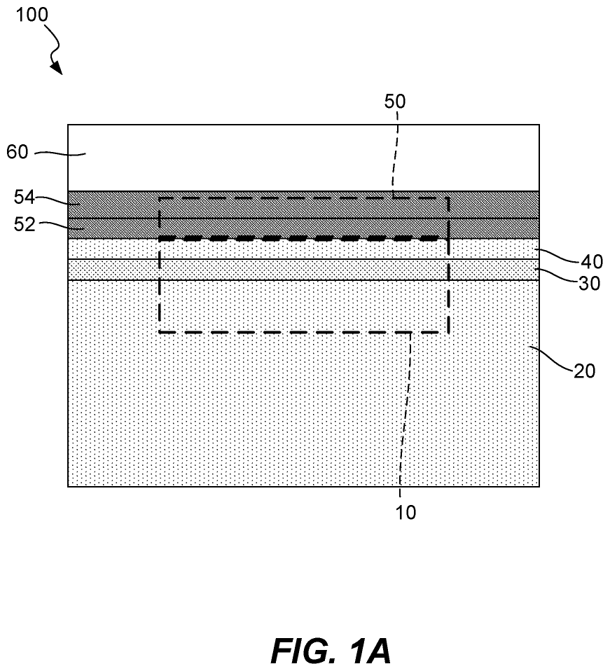

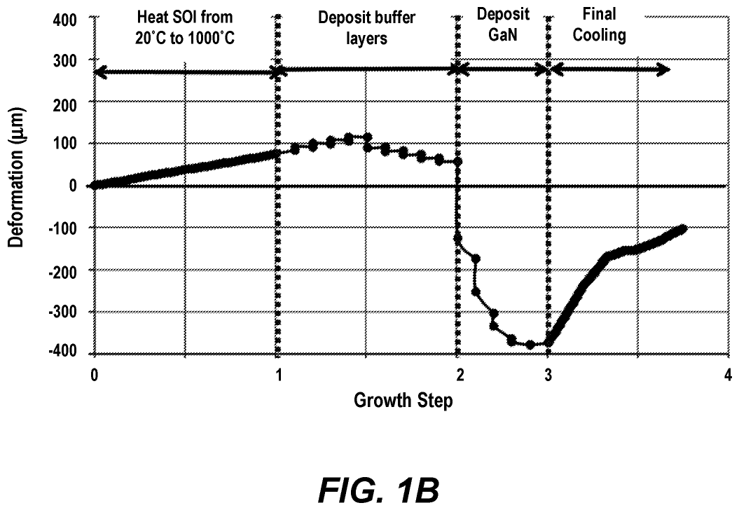

Shown in FIG. 1A is cross-sectional schematic of semiconductor device 100. The substrate of this device is a silicon-on-insulator (SOI) substrate wafer, wherein a semiconductor substrate layer 20 (bulk silicon, 1000 μm) has an insulator layer 30 (SiO₂, 2 μm), disposed thereon, followed by a silicon top layer 40 (2 μm) disposed on the insulator layer 30. The combination of the SOI layers together are denoted as element 10, hence for the purpose of this disclosure “SOI layers”, or “SOI substrate”, or “silicon-on-insulator substrate” will refer to the same layered components and will be collectively referenced as element 10 in the corresponding Figures. Buffer layer 50 is disposed on the surface of the silicon top layer 40. The buffer layer 50 is comprised of a nucleation layer 52 having thickness of about 0.2 μm, typically comprised of AlN, and an AlₓGa₍₁₋ₓ₎N layer 54, where 0<x<1, with a thickness of about 0.3 μm. The semiconductor layer 60 is deposited on top of buffer layer 50. The semiconductor layer 60 is a thick gallium nitride (GaN) layer, having a thickness of about 10 μm.

Depicted in FIG. 1B is a simulation graph showing the magnitude of deformation which occurs during the various processing and deposition steps of the semiconductor device 100, shown in FIG. 1A. The first processing step requires that the SOI substrate 10 is heated from 20° C. to about 1000° C. (+/−30° C.). The buffer layer 50 is then deposited on the SOI substrate 10 at this elevated temperature. The AlN nucleation layer 52 is deposited first, at a temperature of about 970° C., followed by, AlₓGa₍₁₋ₓ₎N layer 54, deposited at a temperature of about 1000° C.° C. (+/−30° C.). Subsequently, the GaN layer 60 is deposited on top of layer 54. The deposition of GaN layer 60 occurs at temperature of about 1000° C. (+/−30° C.).

As is evident from the graph shown in FIG. 1B, various deformations happen to the SOI substrate 10 during these processing steps. When the SOI substrate 10 is first heated to about 1000° C., a deformation in the range of about 100 μm happens (as shown by a positive curve increase on the y-axis). This positive deformation is typically referenced as a concave deformation, resulting in concave bowing of the SOI substrate. During deposition of a thick GaN layer 60 the SOI substrate 10 experiences a deformation shown as a downward curve, in a negative y-axis direction. This negative deformation is characterized as a convex deformation. The deformation occurring during the GaN deposition step is significant and results in convex deformation of nearly 400 μm. Once deposition has concluded and the entire semiconductor device 100 is allowed to cool to room temperature, a concave deformation occurs again, resulting in a final deformation of about 100 μm.

The magnitude of process deformation and of final deformation is significant and problematic as it is beyond acceptable limits for these structures. There are two main issues occurring during this GaN device processing and deposition which need to be controlled or mitigated. The first is the process deformation which is occurring during the deposition of the various layers, and particularly of the GaN layer, where a near 400 micron convex deformation is occurring as the deposition step proceeds (See growth step 2 to 3 in FIG. 1B). When this magnitude of deformation happens during GaN layer deposition, it can cause cracking in the layer, which is a permanent defect that renders the resulting device unusable. The second issue is the final deformation of the entire structure, once the device 100 has undergone a final cooling to room temperature. The final deformation is shown in FIG. 1B as having a magnitude of about 100 micron, in a negative y-axis direction, denoting that the final structure has about 100 micron magnitude convex bowing. The bowing of the final structure is also not desirable, as there are deformation limits in the semiconductor industry which devices have to meet to be operable for specific final applications. Bowing of the substrate is also problematic as it prevents the subsequent standard processing of the wafers required for device fabrication, separation and packaging (e.g., photolithography, etching, metal deposition, dicing, etc.).

When using an SOI type substrate, such as SOI 10 shown in FIG. 1A, as previously discussed, the SOI is comprised of a film of single crystalline Si layer separated by a layer of SiO₂ from the bulk Si substrate. The presence of SiO₂ insulating layer 30 in contact with Si top layer 40, and Si base layer 20, introduces stresses in the SOI structure, for example, due to a large difference in the coefficient of thermal expansion (CTE) of Si and SiO₂. During the cooling of a SOI wafer to room temperature, the silicon substrate contracts more than the oxide layer resulting in a compressive thermal stress in the oxide layer. In addition to thermal stress, compressive stress due to volume expansion, commonly referred as intrinsic stress, is also developed in the oxide layer during oxidation process. The stresses lead to bending of the SOI wafer, which result in the convex or concave bowing and warping of the substrate. Therefore it is very critical to understand and control the process-induced stresses in SOI wafer in order to meet the stringent bow and warp specifications.

In light of the above, it is desirable to not only reduce final bowing or warping deformations of the formed semiconductor device 100, but also mitigate the process related deformation during deposition steps. It is preferred to control the process deformations to a magnitude of less than 400 μm. As to final deformation of the semiconductor structure 100, it is desirable to have a magnitude of less 100 μm, or less than 75 μm, or less than 50 μm, or less than 30 μm, or preferably even less than 20 μm.

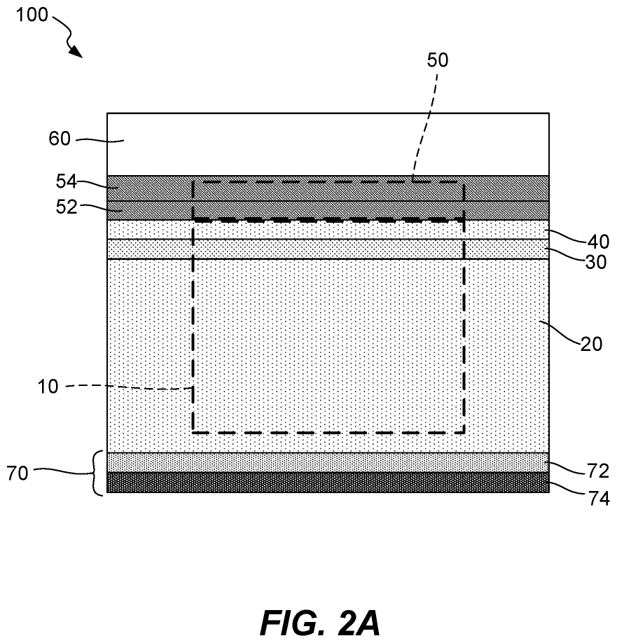

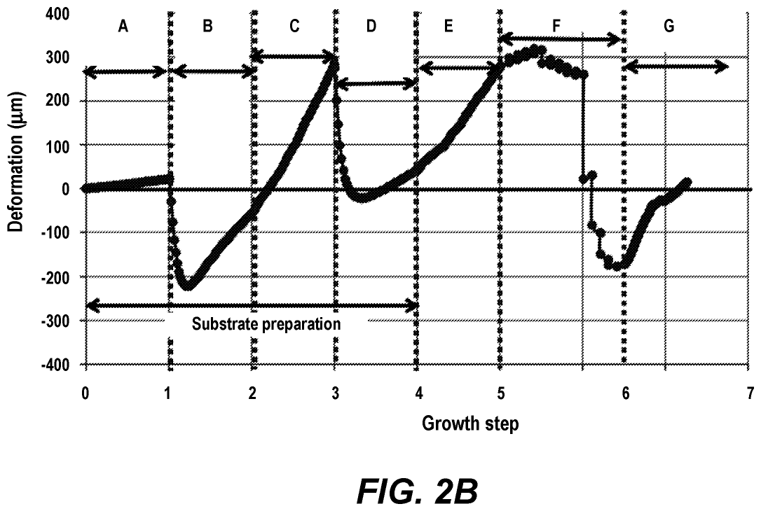

In one embodiment a method of reducing process or final deformation of a gallium nitride (GaN) semiconductor device 100 during a manufacturing process is disclosed. In the embodiment depicted in FIG. 2A, the method includes forming at least one multi-layered structure 70 on at least one surface(s) a semiconductor substrate 20 and depositing a gallium nitride (GaN) semiconductor layer 60 on the semiconductor substrate 20. The at least one multi-layered structure 70 is formed by applying a first amorphous layer 72 on the at least one surface(s) of the semiconductor substrate 20, the first amorphous layer having a first thermal expansion coefficients (CTE), and applying a second amorphous layer 74 on the first amorphous layer 72, the second amorphous layer 74 having a second thermal expansion coefficient, different from the first thermal expansion coefficient.

The first thermal expansion coefficient of the first amorphous layer 72 is greater than a thermal expansion coefficient of the semiconductor substrate 20, and the second thermal expansion coefficient of the second amorphous layer 74 is less than the thermal expansion coefficient of the semiconductor substrate 20. In the embodiment depicted in FIG. 2A, the semiconductor substrate 20, is thick bulk silicon structure of about 1000 μm, and is part of a layered SOI substrate 10, the SOI 10 having a SiO₂ insulator layer 30, followed by a thin crystalline silicon top layer 40, both about 2 μm thick. The multi-layered structure 70 is formed, disposed, or applied on a bottom side of substrate 20. By incorporating a first amorphous layer 72 onto substrate 20 having a greater thermal expansion coefficient, and in contact with a second amorphous layer 74, which has a different thermal expansion coefficient, the bowing deformations occurring during processing of the device 100 can be mitigated or compensated, so that a final deformation of the resulting device 100 after cooling can be significantly flatter, than the device shown in FIGS. 1A and 1B, which has a final deformation of about 100 μm in a convex configuration.

The primary theory behind incorporation of at least two amorphous layers having contrasting thermal expansion rates is to offset the deformations occurring during heating, deposition and cooling steps during processing of device 100. As the device 100 is cooled, the various layers contract according to their respective CTEs. A layer with a greater CTE contracts more than a layer with a lower CTE. The different rates of contraction will cause stress between adjacent layers and result in convex or concave bowing of the overall structure. It is important to note that the amount of stress is also dependent on the thickness of the layers. For example, as a layer becomes thicker, its contribution to the amount of stress will increase accordingly. It is important to choose, material layers, a deposition temperature of said layers, and a thickness of said layers, based on the compensation that these layers will be able to provide the device 100 during processing, heating and cooling steps.

For example, in the embodiment shown in FIG. 2A the first amorphous layer 72 can be comprised of silicon nitride (SiN) and is deposited having thickness of about 3 μm. The deposition temperature of this layer is chosen to be about 300° C. SiN has a greater thermal expansion coefficient than the silicon substrate layer 20 which it is deposited on. This means that during cooling of the structure, the SiN layer will contract more than the silicon substrate layer 20. A second amorphous layer 74, is then deposited onto the first amorphous layer 72. In one embodiment the material of the second amorphous layer is SiO₂, which has a smaller thermal expansion coefficient than the silicon substrate layer 20, which means that during a cooling step it will contract less than the silicon substrate layer 20. The deposition temperature of the SiO₂ layer is about 1000° C. The respective contrasting thermal expansion rates or coefficients (CTEs) of the SiN and the SiO₂ amorphous layers will mitigate and offset the various concave and convex bowing deformations which will occur during GaN deposition processing of the overall device 100, and will result in reduced process deformations, and also a reduced final deformation of the cooled device 100.

This is evidenced in the graph of FIG. 2B, where first the SOI substrate 10 is heated to 300° C. (shown as growth phase A), then SiN is deposited at 300° C. and cooled to 20° C. (growth phase B). During growth phase B a negative deformation (a convex bow) occurs during the cooling process from 300° C. to 20° C. This is followed by positive deformation (a concave bow) during the heating process (C) wherein the structure is heated to about 1000° C. Then SiO₂ is deposited at around 1000° C. and cooled to 20° C. (growth phase D) and as shown this introduces a positive deformation (or concave bow) during the cooling process (D). At the end of growth phase D, the combination of the SiN and SiO₂ amorphous layers brings the SOI substrate 10 to a near flat configuration, showing a very minor concave deformation of about 20 μm. In growth phase E, the SOI substrate 10 is then heated to 1000° C., followed by deposition of buffer layer 50 and GaN layer 60 (growth phase F), which occur at a temperature range of 970° C. to 1000° C. (+/−30° C.). During a final cooling step (G) where the structure 100 is cooled to 20° C., the resulting final deformation is shown to be minimal, less than 20 μm. Hence, in this embodiment the inventors show that choosing these specific deposition temperatures for applying a first amorphous layer 72 and second amorphous layer 74, both layers having contrasting thermal rates of expansion, the process deformation and the final deformation can be offset, compensated and/or controlled, so that a resulting final structure 100 shows minimal bowing or warping. This is in contrast to FIG. 1A, where the multi-layered structure 70 is not present, and the final deformation is in a magnitude of about 100 μm (FIG. 1A showing negative, convex bowing of final structure of about 100 μm, after cooling step).

In one embodiment, the multi-layered structure 70, which is used to compensate for the process and final deformations occurring, will have a two-layered structure, such as that shown in FIG. 2A, where a first amorphous layer 72 is applied, followed by a second amorphous layer 74. In some embodiments, the first amorphous layer 72 materials can be selected from SiN, SiCₓO₍₁₋ₓ₎, SiC, SiNₓO₍₁₋ₓ₎, Al₂O₃, and Cr₂O₃, or a combination thereof, wherein 0<x<1, and the second amorphous layer materials are selected from SiO₂, SiCₓN₍₁₋ₓ₎, or a combination thereof, wherein 0<x<1. In an embodiment, the first amorphous layer can comprise one or more layers selected from SiN, SiCₓO₍₁₋ₓ₎, SiC, SiNₓO₍₁₋ₓ₎, Al₂O₃, and Cr₂O₃, or a combination thereof, wherein 0<x<1, and the second amorphous layer can comprise one or more layers selected from SiO₂, SiCₓN₍₁₋ₓ₎, or a combination thereof, wherein 0<x<1 (for example two, three or four layers). These materials are selected so that a first amorphous layer has a CTE greater than the substrate layer it is deposited on, and the second amorphous layer has a CTE less than the substrate layer in the given embodiment. The temperature of deposition for the first and second amorphous layers (72, 74) is chosen so that it can effectively counter the deformations occurring during heating and cooling processes during fabrication of the device 100.

In one embodiment the temperature of deposition for the first amorphous layer 72 is in the range of about 200° C.-400° C., or about 250° C.-350° C., or preferably about 300° C. The second amorphous layer 74 is deposited at a temperature range of about 800° C.-1100° C., or about 950° C.-1050° C., or more preferably about 1000° C.

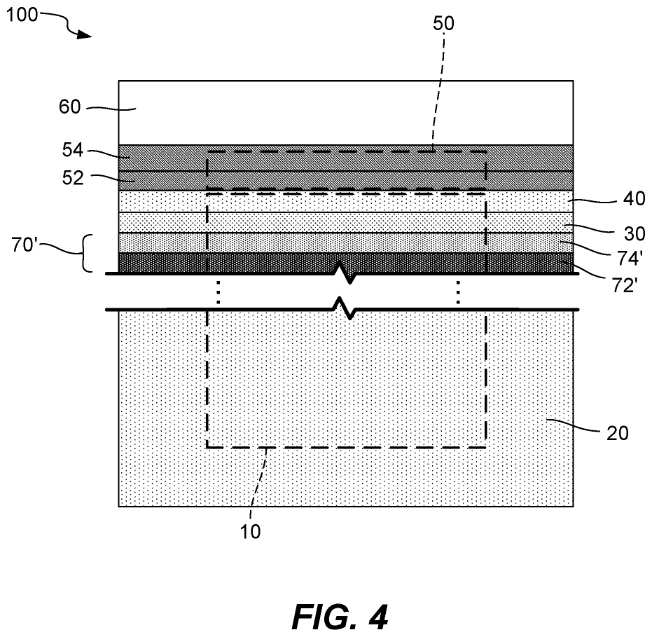

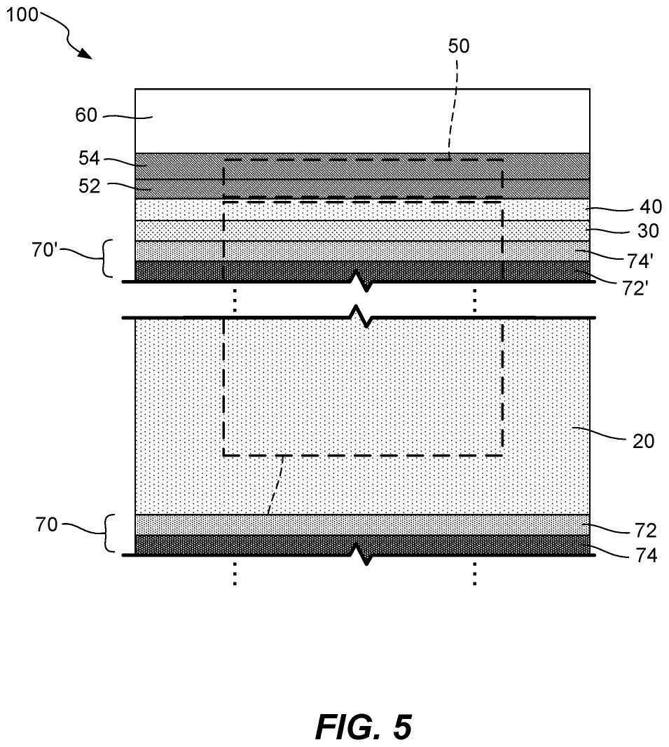

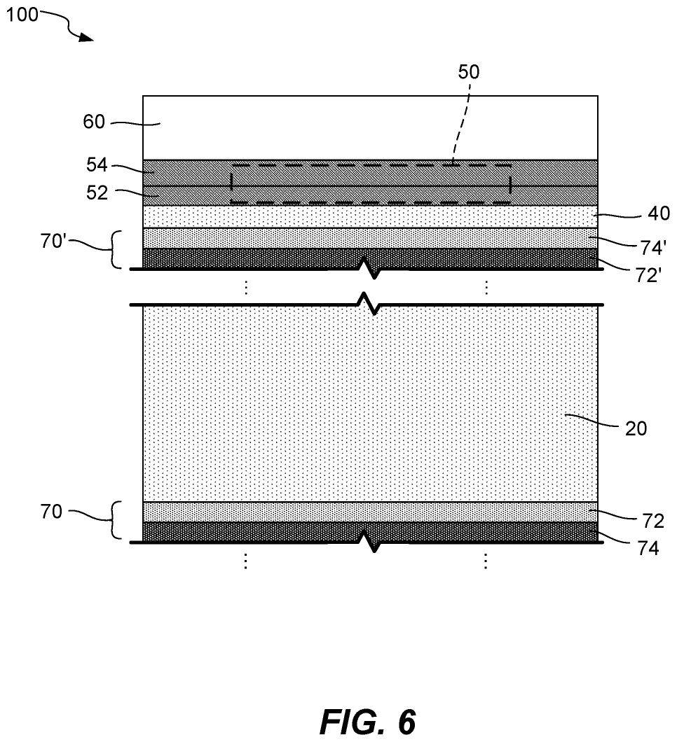

The multi-layered structure 70, can be formed on various surfaces of the wafer substrates. In one embodiment, the multi-layered structure 70 is deposited on bottom side of the substrate, such as is shown in the embodiment of FIG. 2A, previously discussed above. In other embodiments, the multi-layered structure is formed on a bottom and top side of a semiconductor substrate, such as for example, when the substrate is a silicon-on-insulator substrate, SOI substrate 10, a multi-layered structure 70′ is deposited between a SiO₂ insulator layer 30 and the silicon substrate layer 20, such as is shown in FIG. 4. In other embodiments, a multi-layered structure 70′ is deposited between a silicon top layer 40 and a substrate layer 20, as shown in FIG. 6. In other embodiments, a multi-layered structure 70 is deposited on a bottom side of a substrate, and second multi-layered structure 70′ is deposited on a top side of a substrate, such as is shown in embodiments depicted in FIG. 5 and FIG. 6, details of which will be discussed in later section of the disclosure. In further embodiments, the multi-layered structures described herein comprise more than two amorphous layers, for example, three, four, five, six and so on. The primary criteria is that the amorphous layers are deposited in an alternating pattern of thermal expansion coefficients, so that an offset or compensation in deformation can occur during processing steps, as discussed above.

In one embodiment, the deposition thickness and deposition temperature of the various amorphous layers is calculated, determined or selected based on a predetermined desired thickness of the gallium nitride (GaN) semiconductor layer. The amorphous layers to be deposited can be evaluated based on various stress parameters, and based on this evaluation, a thickness of the layers, a deposition temperature, and a layering pattern can be chosen to arrive at desired reduction in bowing or warping deformations. To evaluate the stress that device 100 undergoes during the various processing steps, three sources of stress can be considered and/or calculated: epitaxial growth stress, interface lattice mismatch stress and thermal stress. For the heating and cooling steps, the thermal stress is the dominant stress component that can cause a structural deformation. For the growth process at a steady-state temperature, the epitaxial growth stress and interface lattice mismatch stress are the dominant factors that affect changes in structure of device 100.

By estimating at least one of epitaxial growth stress, interface stress, and thermal stress of the substrate components and the various layers to be deposited, at a selected temperature and a selected thickness, a determination can be made about the deposition parameters of the various layers, including desired deposition temperature, layer thickness, and amorphous layer material, arrangement or placement.

The estimated epitaxial growth stress can be determined by a theoretical calculation, and the estimated interface stress is determined by a lattice constant at the selected temperature. The estimated thermal stress present in the structure can be determined by applying the following equations to each of the layers to be deposited, including the substrate, the amorphous layers, the buffer layers and the GaN layer.

$$\{ ε \} = {[ D ]}^{- 1} \{ σ \} + \{ {ε}^{th} \} \qquad Equation 1$$

$$\{ {ε}^{th} \} = {a}_{e} \times Δ T = {a}_{e} ( T - {T}_{ref} ) \qquad Equation 2$$

$$\{ σ \} = [ D ] \{ ε \} \qquad Equation 3$$

where {ε} is overall strain, {ε^{th}} is thermal strain, de is a material coefficient of thermal expansion (CTE), T is a selected temperature, T_{ref} is a reference temperature, [D] is a strain-stress matrix, and {σ} is a stress matrix.

In embodiments, the semiconductor substrate of device 100 can include a silicon-based substrate, such as silicon-on-insulator (SOI) substrate, a silicon-on-sapphire substrate (SOS) substrate, a bonded silicon substrate, a bulk silicon substrate, including a doped or un-doped bulk silicon substrate, or other such substrates which are known to those of skill in the art, that are suitable for thick GaN layer deposition, including sapphire substrates and silicon carbide (SiC) substrates.

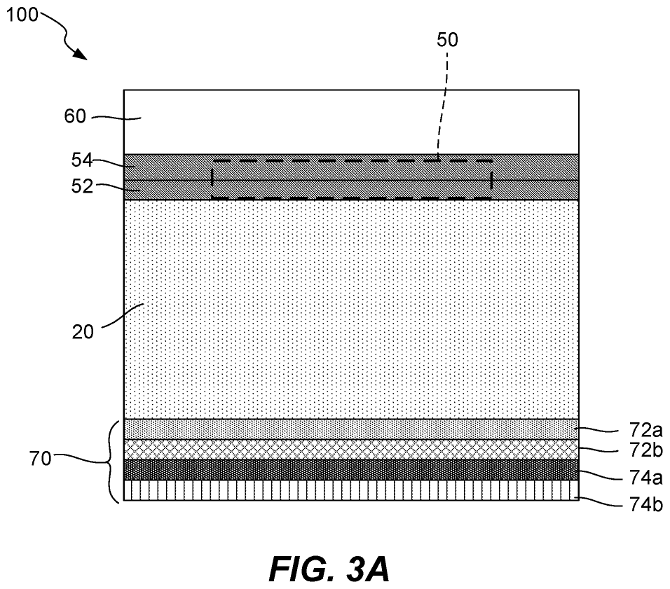

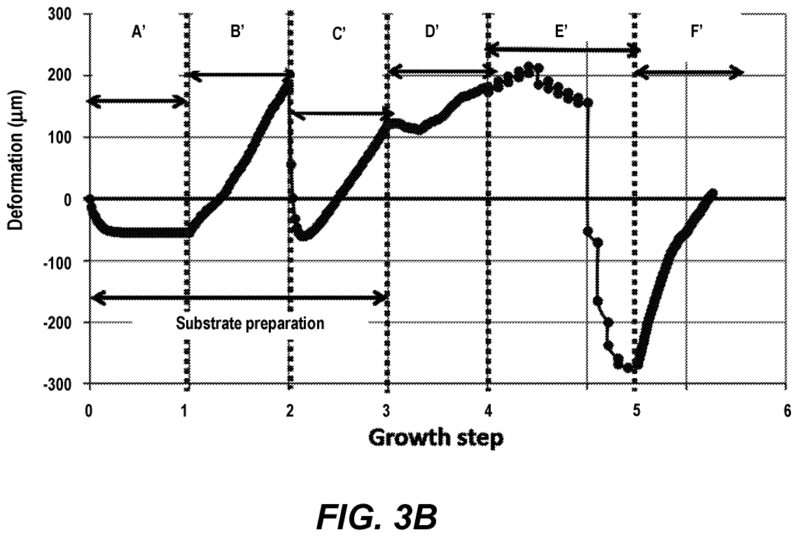

In one embodiment, as depicted in FIG. 3A, the substrate 20 is a silicon bulk substrate, which is solely comprised of a silicon layer, instead of the multiple layered SOI substrates configurations discussed previously. A method of manufacturing a gallium nitride (GaN) semiconductor device 100 is disclosed with respect to this embodiment. The method includes depositing at least one multi-layered structure 70 on a bottom side and/or a top side of a semiconductor substrate 20, followed by depositing a buffer layer 50 on a top side of the semiconductor substrate 20. Subsequently depositing a gallium nitride (GaN) semiconductor layer 60 on the buffer layer 50. The at least one multi-layered structure 70 is comprised of a first amorphous layer 72a and second amorphous layer 72b, with materials for either layer 72a or 72b selected from SiN, SiCₓO₍₁₋ₓ₎, SiC, SiNₓO₍₁₋ₓ₎, Al₂O₃, and Cr₂O₃, or a combination thereof, wherein 0<x<1. The first and second amorphous layers 72a and 72b are deposited at a temperature range of about 200° C.-400° C., or about 250° C.-350° C., or preferably about 300° C. The multi-layered structure 70 further comprises a third amorphous layer 74a and fourth amorphous layer 74b, selected from SiO₂, SiCₓN₍₁₋ₓ₎, or a combination thereof, wherein 0<x<1. The third and fourth amorphous layers 74a and 74b are deposited at a temperature range of about 800° C.-1000° C., or about 850° C.-950° C., or preferably about 900° C.

In a further embodiment of the device 100 shown in FIG. 3A, the first amorphous layer 72a is a SiN layer having thickness of about 2 μm, and the second amorphous layer 72b is a SiCO layer deposited to a thickness of about 4 μm. Both of these layers are deposited at a temperature of about 300° C. The third deposited amorphous layer 74a is a SiO₂ layer, deposited at a thickness of about 5 μm, and the fourth amorphous layer 74b is a SiCN layer, deposited at a thickness of about 2 μm. In this embodiment, the deposition temperature of the third and fourth amorphous layers 74a and 74b is about 900° C. The deformations device 100 undergoes during processing of this four layered compensation for the substrate are shown in FIG. 3B.

Deposition of the SiN layer 72a and SiCO amorphous layer 72b occurs at 300° C. followed by a cool down to 20° C. (this is shown as growth phase A′ in FIG. 3B). The substrate 20 is then heated to about 900° C. during growth phase B′. Once the substrate is heated to this temperature, the deposition of the third and fourth amorphous layers 74a and 74b occurs (SiO₂ and SiCN respectively) at this temperature followed by cool down to 20° C., shown as growth phase C′. Following this step, the substrate 20, having the multi-layered structure 70 deposited thereon on the bottom side of the substrate, is then heated to about 1000° C. during phase D′, followed by the buffer layer 50 and GaN layer 60 deposition during growth phase E′. As a final cooling step to 20° C. occurs in growth phase F′, it is evident that the final deformation of the device 100 is relatively minimal, at about 10-15 μm, as evidenced in the final data point in FIG. 3B. This is due to the offset and compensation which was provided by the multi-layered structure 70 formed on the bottom side of substrate 20.

In this embodiment the SiN and SiCO layers are chosen for the first and second amorphous layers 72a and 72b because of their similar thermal expansion coefficient (CTE), i.e. their similar rate of expansion or contraction in heating or cooling processes. Both of the material layers have CTEs which are higher than that of the silicon substrate 20 in this embodiment. The material selected for layer 72a and 72b is not limited, for examples the materials may be reversed, so that a SiCO layer is deposited first, followed by an SiN layer. Similarly, the SiO₂ and SiCN materials are purposefully selected as the third and fourth amorphous layer materials because they have similar CTEs to each other, both having CTEs less than the CTE of the silicon substrate 20, and the combination of these four layers, deposited at the chosen temperatures of about 300° C. and 900° C. for the respective layers, results in optimal bowing compensation during processing steps, and also results in a reduced final deformation of device 100, as is evident by the graph of FIG. 3B. As noted above, the order of materials used for the third and fourth amorphous layers can also be switched, with the SiCN layer deposited first, followed by a SiO₂ layer.

In addition to the materials disclosed in the foregoing embodiments, other amorphous materials may be used for any of the amorphous layers, as long as they have CTEs which follow the guidelines outlined above, with respect to the CTE of the substrate material, and as long as they can be deposited at the chosen temperatures ranges of 200° C.-400° C. and 800° C.-1100° C. Additionally, although the configuration shown in FIG. 3A has the multi-layered structure 70 deposited on a bottom side of the silicon substrate 20, in an alternate embodiment, the multi-layered structure may be deposited on a surface of the top side of the substrate 20, before deposition of the buffer layer 50 and GaN layer 60.

As discussed above, the multi-layered structure used for reducing the deformations in the wafer substrate can be deposited on various surfaces of a substrate, including a top side surface. One such embodiment is show in FIG. 4, where a multi-layered structure 70′ is deposited on a top side of a substrate. In this embodiment, an SOI substrate 10 is shown having substrate base layer 20, insulator layer 30 and silicon top layer 40. Prior to deposition of the insulator layer 30 and silicon top layer 40, a first amorphous layer 72′ can be deposited on the silicon base layer 20, followed by a second amorphous layer 74′ deposited onto the first amorphous layer 72′. Other additional amorphous layers can also be deposited, similarly as shown in FIG. 3A, where three, four five, six layers and so on are deposited for purposes of offsetting and mitigating substrate deformation. For example, two or three different amorphous layers are deposited first having a CTE greater than that of the silicon base layer 20, and then an additional two or three amorphous layers are deposited having materials with a CTE less than that of the silicon base layer 20. The thickness of each layer and deposition temperature of the layers can be calculated so as to control the amount of stress and strain occurring in the layers during the deposition process, through the parameters and equations discussed above.

An additional embodiment shown in FIG. 5, includes an SOI substrate 10, having the multi-layer structure 70 deposited on a bottom side, in addition to a multi-layered structure 70′ deposited on a top side. The choice of materials for amorphous layers 72 and 72′, will follow the same principles previously discussed with respect to CTEs that are greater than the silicon base substrate layer 20. Similarly the choice of material for amorphous layers 74 and 74′ will be such that their CTE is less than that of the silicon base substrate layer 20. If more than two amorphous layers are included in multi-layer structure 70′ and more than two are included in multi-layer structure 70, then the configuration and order of these layers can for example follow the same order as shown in the embodiment of FIG. 3A, where two or more layers have a similar CTE (72a and 72b), and the additional two or more deposited thereafter have a different CTE (74a and 74b).

In FIG. 6 an additional embodiment is depicted, this time not utilizing an SOI type substrate 10, but a general material substrate 20, which can be a bulk silicon substrate, a sapphire substrate, a silicon carbide substrate, a diamond substrate, or any other type of base substrate material. The general substrate 20 depicted incorporates a silicon top layer 40. Prior to the deposition of the silicon top layer 40, the deformation compensation layers can be formed on the substrate 20. This can be performed on a bottom side and a top side of the general substrate, as shown by multi-layer structures 70 and 70′. Once the deposition of structures 70 and 70′ has been carried out on the substrate 20, then a silicon top layer 40 can be deposited, followed by buffer layer 50 and GaN deposition of layer 60.

Also disclosed are semiconductor devices, fabricated according to the methods described herein, having multi-layered structures as disclosed herein, for purposes of deformation compensation. In one embodiment semiconductor device is disclosed having at least one multi-layered structure(s) formed on at least one surface(s) a semiconductor substrate, and a gallium nitride (GaN) semiconductor layer. The at least one multi-layered structure(s) comprises a first amorphous layer on the at least one surface(s) of the semiconductor substrate, the first amorphous layer having a first thermal expansion coefficients (CTE), and a second amorphous layer on the first amorphous layer, the second amorphous layer having a second thermal expansion coefficient, different from the first thermal expansion coefficient. For purposes of brevity, the various embodiments described above are to be understood as pertaining not only to the methods of manufacturing semiconductor devices, but also to the semiconductor structures themselves fabricated by said methods.

In all embodiments described herein, the thickness of the multi-layered structures 70 and 70′, all amorphous layers 72, 74, 72a, 72b, 72′, 74′, and so on, can be varied and chosen based on the level of deformation compensation that will be required. A thicker deposited GaN layer will result in higher stress and deformation of the substrates disclosed herein, so thicker amorphous layers may be required to be deposited, depending on the thickness of the desired GaN layer. The thickness of the GaN semiconductor layer ranges from about 1 μm-100 μm, or from 5 μm-75 μm, or 10 μm-50 μm, or 15 μm-40 μm, or 20 μm-30 μm. Deposition thickness of the various amorphous layers ranges from about 0.1 μm-30 μm, or 0.5 μm-25 μm or 1 μm to 20 μm, or 2 μm-15 μm, or 3 μm-10 μm, or 4 μm-7 μm, or 5 μm to 6 μm. Buffer layer 50, including nucleation AlN layer 52, and AlₓGa₍₁₋ₓ₎N, layer 54 can be deposited to a variety of necessary thickness, depending on the device type. AlN nucleation layer 52 can be deposited at a temperature ranging from 900° C. to 1100° C. or 970° C. to 1030° C., and to a thickness ranging from less than 0.1 μm to larger than 1 μm, or from 0.1 μm to 1 μm, or from 0.1 μm to 0.3 μm, or 0.2 μm. Layer 54 can be grown at a temperature ranging from 900° C. to 1100° C. or from 940° C. to 1000° C., and to a thickness ranging from less than 0.1 μm to larger than 1 μm, or from 0.1 μm to 1 μm, or from 0.2 to 0.4 μm, or 0.3 μm.

Various deposition methods known in the art can be utilized to grow or deposit the material layers that form the GaN semiconductor devices disclosed herein. Chemical vapor deposition (CVD) techniques are widely used in semiconductor fabrication, such as for example, metalorganic vapor-phase epitaxy, also sometimes referred to as metalorganic chemical vapor deposition (MOCVD). This is a CVD method used to produce single or polycrystalline thin films on substrates. MOCVD techniques and equipment can be utilized to deposit the high temperature deposition layers of the devices disclosed herein. The buffer layers, the GaN semiconductor layers, and the high temperature deposited amorphous layers (SiO₂, SiCN etc.) can be applied using MOCVD. The lower temperature deposited amorphous layers, such as the SiN, SiCO, and so on, can be formed using plasma-enhanced CVD (PECVD) methods and equipment. Other deposition methods can also be employed, and are known to those skilled in the art. The deposition temperature, the material to be deposited, and the thickness of the film to be deposited, will govern which deposition methods are utilized for forming the various layers of the devices disclosed herein.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A method of reducing process and final deformation of a gallium nitride (GaN) semiconductor device, the method comprising:
forming at least one multi-layered structure on at least one surface of a semiconductor substrate; and
depositing a gallium nitride (GaN) semiconductor layer on the semiconductor substrate;
wherein the at least one multi-layered structure is formed by applying a first amorphous layer on the at least one surface of the semiconductor substrate, the first amorphous layer having a first thermal expansion coefficient, and applying a second amorphous layer on the first amorphous layer, the second amorphous layer having a second thermal expansion coefficient, different from the first thermal expansion coefficient.

2. The method of claim 1, wherein the first thermal expansion coefficient is greater than a thermal expansion coefficient of the semiconductor substrate, and wherein the second thermal expansion coefficient is less than the thermal expansion coefficient of the semiconductor substrate.

3. The method of claim 1, wherein the semiconductor substrate comprises at least one of a silicon-based substrate, a silicon-on-insulator (SOI) substrate, a silicon carbide (SIC) substrate, a silicon-on-sapphire substrate (SOS) substrate, a bonded silicon substrate, or doped or un-doped silicon substrate, a sapphire substrate, a diamond substrate, or a combination thereof.

4. The method of claim 1, wherein the first amorphous layer comprises one or more layers selected from SiN, SiCₓO₍₁₋ₓ₎, SiC, SiNₓO₍₁₋ₓ₎, Al₂O₃, and Cr₂O₃, or a combination thereof, wherein 0<x<1, and the second amorphous layer comprises one or more layers selected from SiO₂, SiCₓN₍₁₋ₓ₎, or a combination thereof, wherein 0<x<1.

5. The method of claim 4, wherein the first amorphous layer comprises SiN and is deposited at a temperature range of about 200° C. to 400° C., and the second amorphous layer comprises SiO₂ deposited at a temperature range of about 800° C. to 1100° C.

6. The method of claim 1, wherein the at least one multi-layered structure is formed on a bottom side of the semiconductor substrate, or on a top side of a semiconductor substrate, or a combination thereof.

7. The method of claim 1, wherein the semiconductor substrate comprises a silicon-on-insulator (SOI) substrate and wherein the at least one multi-layered structure is formed between a silicon base layer and a SiO₂ insulator layer of the semiconductor substrate.

8. The method of claim 1, wherein forming at least one multi-layered structure comprises: forming a first multi-layered structure on a bottom side of the semiconductor substrate and forming a second multi-layered structure on a top side of the semiconductor substrate, wherein the second multi-layered structure is between an insulator layer or silicon top layer and a base layer of the semiconductor substrate.

9. The method of claim 1, wherein the first amorphous layer and second amorphous layer have a thickness of about 0.1 μm to 30 μm.

10. The method of claim 1, further comprising calculating a deposition thickness and/or deposition temperature for the first amorphous layer and second amorphous layer, based on a predetermined desired thickness of the gallium nitride (GaN) semiconductor layer.

11. The method of claim 1, wherein the final deformation of the gallium nitride (GaN) semiconductor device is less than about 50 μm.

12. A method of manufacturing a gallium nitride (GaN) semiconductor device, the method comprising:
depositing at least one multi-layered structure on a bottom side and/or a topside of a semiconductor substrate;
depositing a buffer layer on a top side of the semiconductor substrate; and
depositing a gallium nitride (GaN) semiconductor layer on the buffer layer;
wherein the at least one multi-layered structure comprises a first amorphous layer and a second amorphous layer, selected from SiN, SiCₓO₍₁₋ₓ₎, SiC, SiNₓO₍₁₋ₓ₎, Al₂O₃, and Cr₂O₃, or a combination thereof, wherein 0<x<1, and a third amorphous layer and fourth amorphous layer selected from SiO₂, SiCₓN₍₁₋ₓ₎, or a combination thereof, wherein 0<x<1,

13. The method of claim 12, wherein the first amorphous layer and second amorphous layer are deposited at a temperature of about 200° C. to 400° C., and the third amorphous layer and fourth amorphous layer are deposited at temperature of about 800° C. to 1000° C.

14. The method of claim 12, wherein the gallium nitride (GaN) layer is deposited at a thickness of about 1 μm-100 μm.

15. The method of claim 12, wherein a first multi-layered structure is deposited on a bottom side of the semiconductor substrate, and a second multi-layered structure is deposited on a top side of the semiconductor substrate.

16. A semiconductor device, comprising:
at least one multi-layered structure formed on at least one surface a semiconductor substrate;
a buffer layer; and
a gallium nitride (GaN) semiconductor layer;
wherein the at least one multi-layered structure comprises a first amorphous layer, the first amorphous layer having a first thermal expansion coefficients (CTE), and a second amorphous layer formed on the first amorphous layer, the second amorphous layer having a second thermal expansion coefficient, different from the first thermal expansion coefficient

17. The semiconductor device of claim 16, wherein the at least one multi-layered structure comprises a first multi-layered structure on a bottom side of the semiconductor substrate, and a second multi-layered structure on a top side of the semiconductor substrate.

18. The semiconductor device of claim 16, wherein the first amorphous layer and/or second amorphous layer comprise one or more layers of SiO₂, SiCₓN₍₁₋ₓ₎, SiN, SiCₓO₍₁₋ₓ₎, SiC, SiNₓO₍₁₋ₓ₎, Al₂O₃, and Cr₂O₃, or a combination thereof, wherein 0<x<1.

19. The semiconductor device of claim 16, wherein the gallium nitride (GaN) semiconductor layer has a thickness of about 1 μm-100 μm, and the semiconductor device has a final deformation of less than about 50 μm.

20. The semiconductor device of claim 16, wherein the first amorphous layer or second amorphous layer have a thickness of about 0.1 μm to 30 μm.
